(19) United States
(12) Patent Application Publication
(10) Pub. No.: US 2002/0072191 A1
(43) Pub. Date: Jun. 13, 2002

(54) Manufacturing method of semiconductor device

(75) Inventors: Hidemitsu Aoki, Tokyo (JP); Hirofumi Fujioka, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/992,027

(22) Filed: Nov. 26, 2001

(30) Foreign Application Priority Data
Nov. 24, 2000 (JP) 2000-357780

(51) Int. Cl. H01L 21/20; H01L 21/8242

(52) U.S. Cl. 438/396; 438/240

(57) ABSTRACT

A capacitor element is formed by setting a contact hole in an interlayer insulating film 3, forming an adhesive film 5 and a lower electrode film 6, forming a capacitor insulating film 7 thereon, crystallizing this capacitor insulating film 7 by applying irradiation of a laser beam, and forming an upper electrode film. This capacitor element brings out characteristics of the metal oxide material to the utmost limit without diminishing the reliability of the element; or, this capacitor film performs a sufficiently high permittivity and a sufficiently high conductivity.

### FIELD OF THE INVENTION

The present invention relates to a method of manufacturing an element in which a metal oxide is utilized.

### BACKGROUND OF THE INVENTION

In recent years, a highly dielectric film of Ta₂O₅, a perovskite-based material or such has come into use for a capacitor insulating film in the DRAM (Dynamic Random Access Memory) and the FeRAM (Ferroelectric Random Access Memory), in place of a conventional silicon oxide film or silicon nitride film. The use of such a highly dielectric film makes it possible to secure a required storage capacitance within a small occupied area and, thus, improve the degree of integration for the capacitor element.

When a highly dielectric film is employed, it generally becomes necessary to perform annealing at a high temperature of 600-700° C. after the film is grown, for the purpose of attaining a sufficiently high permittivity. Immediately after the film is grown, the highly dielectric film cannot provide the high permittivity, being in the amorphous state. The high permittivity by which the material thereof is characterized does not come out until the step of crystallization through annealing is carried out. However, the requirement to perform the high temperature annealing of this sort brings about the following problems on conventional manufacturing methods.

One problem is that, if polysilicon or such is utilized as the electrode materials to sandwich a capacitor film, the capacitance thereof becomes smaller. As the highly dielectric film is normally made of a metal oxide, by high temperature annealing mentioned above, oxygen is set free from this metal oxide film and oxidizes polysilicon. Therefore, dielectric films (silicon oxide films) having a lower permittivity than the highly dielectric films become present between the electrode materials, and, as a result, the capacitance thereof becomes smaller.

Effective measures to avoid such a drawback are to employ, as the electrode materials, a substance that is unlikely to form an insulating film by the oxidation, for instance, a noble metal such as ruthenium or platinum. Nevertheless, metal materials of this sort are generally known as lifetime killers and when subjected to such an annealing at a high temperature as described above, the material, in some cases, diffuses into and within the silicon substrate at a high speed and causes various ill effects including a decrease in carrier mobility and a change in threshold voltage of the transistor.

Further, since a capacitor section is normally connected with a transistor through an interlayer contact plug, with a high temperature annealing as described above being performed, the interlayer connection plug and an interface between the interlayer connection plug and the capacitor may become oxidized and the resistance, increased.

Meanwhile, besides the high temperature annealing method, the crystallization method with irradiation of the laser beam is also known as a method of forming a capacitor film (Japanese Patent Application Laid-open No. 193472/1999 and Japanese Patent Application Laid-open No. 343642/1993). However, the methods described in these publications only provide methods in which the laser irradiation is applied onto the amorphous film formed on the flat plane and do not provide methods in which the metal oxide formed on the uneven surface is crystallized by the laser irradiation. Because the propagation of the laser light is highly close to rectilinearity, it is not considered, from the common conventional technical understanding, that the laser irradiation can have an effect satisfactorily on the metal oxide formed on the uneven surface, especially on the sidewall sections thereon. In consequence, the application of crystallization technique with the laser irradiation to such a subject has been never investigated. Moreover, when the laser irradiation is applied to the metal oxide formed on the uneven surface, the amount of irradiation of the light presumably varies with the location, and besides, in manufacturing miniaturized capacitor elements, even if defective crystallization arises in the very small part of a capacitor film, the amount of its capacitance changes markedly, which results in a considerable drop in reliability of the products. Accordingly, in the step of crystallization of a capacitor film formed on the uneven surface and, especially in a method of manufacturing a capacitor element which is equipped with such a capacitor film, there have not been reported any investigations to make crystallization by the laser irradiation, and high temperature annealing by means of RTA (Rapidly Thermal Annealing) or such is generally carried out.

In light of the above circumstances, the present invention provides a method of bringing out characteristics of the metal oxide material to the utmost limit without diminishing the reliability of the element. For example, the present invention provides, for a capacitor element, a method of forming a capacitor film with a sufficiently high permittivity and an electrode film with a sufficiently high conductivity.

### SUMMARY OF THE INVENTION

The present invention relates to a method of manufacturing a semiconductor device; which comprises the step of depositing an amorphous metal oxide on a surface of a semiconductor substrate where a sunken section or a raised section is set, and thereafter crystallizing the metal oxide-by irradiation of a laser beam.

Further, the present invention relates to a method of manufacturing a semiconductor device; which comprises the first step of forming an interlayer insulating film having a sunken section on a semiconductor substrate and thereafter forming a lower electrode layer in a region including the internal wall of the sunken section and depositing an amorphous metal oxide thereon; the second step of crystallizing the metal oxide by irradiation of a laser beam; and the third step of forming an upper electrode layer on the metal oxide.

The present invention provides a method of crystallizing fittingly a mental oxide deposited on an uneven surface, especially on the sidewall of a sunken section, thereby bringing out characteristics of the material well. The crystallized metal oxide can be utilized as a capacitor film or an electrode film of a capacitor element.

For example, if Ta₂O₅, BST (BaₓSr₁₋ₓTiO₃), PZT (PbZrₓTi₁₋ₓO₃), PLZT (Pb_{1-y}La_{y}ZrₓTi₁₋ₓO₃) or SrBi₂Ta₂O₉ (0<x<1, 0<y<1) is chosen as a metal oxide, its permittivity increases steadily with irradiation by a laser beam and a capacitor film with a high permittivity can be obtained.

On the other hand, when an oxide of Ru or Pt is chosen as a metal oxide, its conductivity increases steadily with irradiation by a laser beam and a good proper electrode film can be obtained.

In recent years, viewed from the point of improving the degree of integration, the steric structures, such as stack type one, and trench type one have become more often employed for the structure of capacitor elements. In the structure of this sort, it may be required to form a capacitor film or an electrode film on the sidewall of a hole that is set in a semiconductor substrate or an interlayer insulating film laid thereon; or to form a capacitor film or an electrode film on the sidewall of a raised section that is set on the substrate surface. The present invention can apply well to such a steric structure as described above, whereby the whole capacitor film can be crystallized uniformly and the permittivity thereof, heightened. Likewise, the whole electrode film can be crystallized uniformly and a stable conductivity, attained.

As set for the above, in the present invention, crystallization of the metal oxide can be made in the steps performed at low temperatures so that characteristics of the metal oxide material can be brought out to the utmost limit without diminishing the reliability of the element.

For example, in a capacitor element, a capacitor film with a sufficiently high permittivity and an electrode film with a sufficiently high conductivity can be formed without diminishing the reliability of a plug that makes connection between a transistor and a capacitor therein.

### BRIEF DESCRIPTION OF THE DRAWINGS

FIG. 1 is a series of views illustrating the steps of a method of manufacturing a semiconductor device according to the present invention.

FIG. 2 is a series of views illustrating the following steps of the method of manufacturing a semiconductor device according to the present invention.

FIG. 3 is a view illustrating the following step of the method of manufacturing a semiconductor device according to the present invention.

FIG. 4 is a series of views illustrating the steps of another method of manufacturing a semiconductor device according to the present invention.

FIG. 5 is a series of views illustrating the following steps of the method of manufacturing a semiconductor device according to the present invention.

### DESCRIPTION OF THE PREFERRED EMBODIMENT

A method of manufacturing a semiconductor device according to the present invention may comprise:

(a) the first step of forming an interlayer insulating film having a sunken section on a semiconductor substrate and thereafter forming a lower electrode layer in a region including the internal wall of the sunken section and depositing an amorphous metal oxide thereon;

(b) the second step of crystallizing the metal oxide by irradiation of a laser beam; and

(c) the third step of forming an upper electrode layer on the metal oxide.

In step (a), in addition to a method of forming an interlayer insulating film on a semiconductor substrate and thereafter forming a sunken section by etching this interlayer insulating film, a method of growing a film on an underlying face on which a sunken section has been already formed and thereby forming an interlayer insulating film having a sunken section can be employed.

In the above method of manufacturing a semiconductor device, between the first step and the second step, the step of removing the metal oxide formed in the region other than the sunken section by means of chemical mechanical polishing can be performed. In order to crystallize the inside of the sunken section thoroughly, it is necessary to raise the energy density of the laser beam sufficiently. Nevertheless, the investigation of the present inventors demonstrated that, with this done, there are instances where the film material agglomerates in the plane region other than the sunken section, creating anomalous bodies. This is considered to result from a fact that the laser beam having a suitable energy for the film inside of the sunken section may have the excessive energy for the film in the region other than the sunken section. Such anomalous bodies, possibly causing not only faults in the subsequent film growth but also wafer contamination or cross contamination between apparatuses, are the primary factor for a considerable drop in reliability of the element. As a method of preventing such anomalous bodies to be created, it is effective to introduce, between the first step and the second step, the step of removing the metal oxide formed in the region other than the sunken section by means of chemical mechanical polishing. Hereat, the laser irradiation is only made in the state that amorphous films formed in the regions other than the sunken section are all removed so that creation of anomalous bodies can be prevented.

Further, in the above method of manufacturing a semiconductor device, between the second step and the third step, the step of polishing the surface in the region other than the sunken section by means of chemical mechanical polishing can be performed. By this polishing, the metal oxide film formed in the plane region other than the sunken section is removed. Therefore, anomalous bodies created by the laser irradiation, for example, agglomerations of the metal oxide or the like are removed so that faults in the subsequent film growth can be prevented.

In the above method of manufacturing a semiconductor device, the lower electrode layer, although possible to employ polysilicon, can be made of a metal material that contains one or more elements selected from the group consisting of Ru, Pt and Ir. In this way, the amorphous film present inside of the sunken section can be crystallized more uniformly. The reason for this has not been fully elucidated yet, but presumably the explanation lies in a fact that, with more laser irradiation beam being reflected from the laser electrode layer, the ample energy of laser beam is given to the sidewall of the sunken section and the like. Further, as the material for the lower electrode layer, a material containing Ti, Ta or W can be also utilized. In this way, the advantages of achieving high quality in the film growth inside of the sunken section and the like can be obtained.

First Embodiment

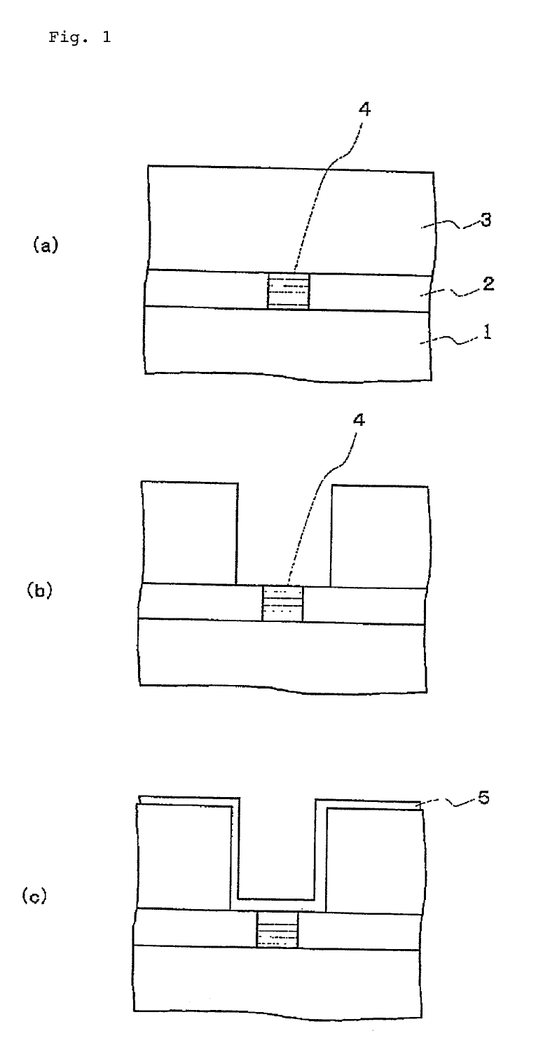

Next, taking the case of manufacturing steps for a capacitor in a DRAM as an example, the preferred embodiment of the present invention is described in detail, with reference to FIGS. 1-3. In the present embodiment, there is formed a capacitor with a structure wherein layers of a lower electrode film, a capacitor insulating film and an upper electrode film are laid in a sunken section that is set within an insulating film lying over a semiconductor substrate. Here, for convenience of the explanation, a capacitor section is shown somewhat enlarged in the drawings.

First, as shown in FIG. 1(a), after a MOS (Metal-Oxide-semiconductor) transistor comprising a source-drain diffusion region (omitted from the drawings) is formed on a silicon substrate 1, an interlayer insulating film 2 is formed on the entire surface of the silicon substrate 1. Next, over the diffusion region, which is not shown in the drawings, a contact plug 4 is formed. For the filling-up material of the contact plug 4, polysilicon, tungsten or the like can be used. After the plug formation, the entire surface of the substrate is made flat and an interlayer insulating film 3 is formed thereon.

Next, by performing dry etching, a hole to reach the contact plug 4 is formed through the interlayer insulating film (FIG. 1(b)). The cross-section of the hole is preferably made a circle, an ellipse or such. A bore of the hole is set to be, for example, 0.1-0.5 μm. Further, from the point of view of improving the capacitor element density, a depth-of the hole is set to be preferably 0.2 μm or greater, and more preferably, 0.4-3 μm while an aspect ratio thereof is set to be preferably 1 or greater and more preferably 3-20.

An adhesive film 5 is then formed over the entire surface of the substrate (FIG. 1(c)). The adhesive film may be, for example, a TaN film, a WN film or a layered film in which layers of Ti and TiN are laid in this order, and it may be grown by the sputtering method, the CVD (Chemical Vapor Deposition) method or the like.

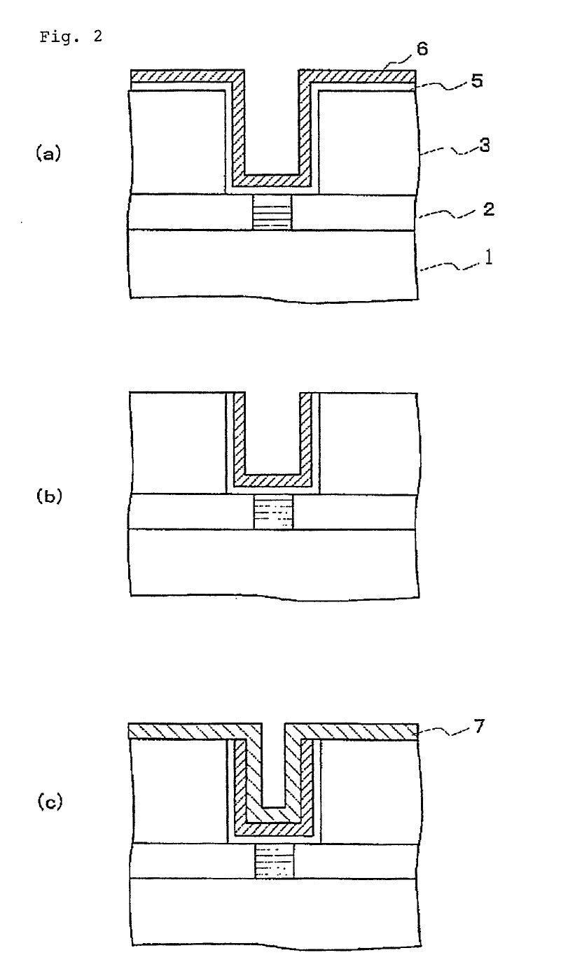

Next, a lower electrode film 6 made of ruthenium is formed over the entire surface of the substrate (FIG. 2(a)). Using ruthenium as the electrode material, a decrease in capacitance due to the oxidation of the electrode material can be prevented effectively and besides, the production cost can be reduced. As a method of growing a ruthenium film, the sputtering method, the CVD method or the like can be employed, but the CVD method is favored the best among these methods, since the CVD method is the most suitable to form a thin film of ruthenium uniformly with good coverage inside of the narrow hole shown in FIG. 2(a). In case the CVD method is employed, for example, bis(ethylcyclopentadienyl) ruthenium can be used as a source gas.

Next, in order to remove ruthenium-based metals attached to the surface other than the element formation region-of the silicon substrate, a treatment with a removing solution is performed. With this, a lowering of element reliability or cross contamination between the apparatuses for the film growth that may be caused by ruthenium can be prevented. For the removing solution, there is used, for instance, a solution containing the following compounds: (a) and/or (b), and optionally, (c);

(a) one or two acids selected from chloric acid, perchloric acid, iodic acid, periodic acid,

(b) one or two salts selected from salts containing bromine oxide ions, salts containing manganese oxide ions and salts containing tetravalent cerium ions,

(c) an acid selected from the group consisting nitric acid, acetic acid, iodic acid, chloric acid and periodic acid.

As the acid, it is favorable to use one or more acids selected from the group consisting nitric acid, perchloric acid and acetic acid. The examples of the preferable solution are:

1) mixture of cerium ammonium nitrate and nitric acid,

2) mixture of periodic acid and nitric acid.

Using such a removing solution, ruthenium-based metals can be removed with effect and, in addition, ruthenium-based metals once removed can be prevented from reattaching thereto with effect.

Subsequently, unnecessary parts of the adhesive film 5 and the lower electrode film 6 are removed by means of etching back or chemical mechanical polishing (CMP). The state after the removal is shown in FIG. 2(b). In this way, the adhesive film 5 and the lower electrode film 6 are made to reach the same level of height as that of the interlayer insulating film 3, whereby it becomes possible to prevent the lower electrode film 6 shown in the drawing from touching electrodes of other neighboring capacitors.

Next, a capacitor insulating film 7 made of Ta₂O₅ is formed over the entire surface of the substrate (FIG. 2(c)). The capacitor insulating film 7 can be grown, for example, by the CVD method using pentaethoxytantalum and oxygen as the main materials. For the metal oxide to constitute the capacitor insulating film 7, in addition to Ta₂O₅, perovskite-based materials such as BST (BaₓSr₁₋ₓTiO₃), PZT (PbZrₓTi₁₋ₓO₃), PLZT (Pb_{1-y}La_{y}ZrₓTi₁₋ₓO₃) or SrBi₂Ta₂O₉ (0<x<1, 0<y<1) can be utilized. The method of growing a capacitor insulating film of these sorts is not specifically limited, and the CVD method, the sol-gel method, the sputtering method or the like can be used.

The capacitor insulating film 7 immediately after the growth is in the amorphous state and the high permittivity by which the material thereof is characterized does not come out. In conventional techniques, crystallization is normally made by performing ramp anneal at 600-700° C., subsequently. In contrast with this, in the present embodiment, crystallization is made by irradiating thereon with a laser beam.

As a light source for the laser beam, in addition to excimer lasers of XeCl, KrF, ArF, F₂, XeF or such, a solid-state laser or the like can be used. Furthermore, it is possible to use any or these lasers in combination with a dye laser having a required emission wavelength. Among these, excimer lasers of XeCl, KrF and ArF, which can readily provide sufficiently high energy densities, are preferably used. The average energy density for the laser beam is preferably not less than 100 mJ/cm², more preferably not less than 150 mJ/cm² and most preferably not less than 200 mJ/cm²; but preferably not greater than 450 mJ/cm², more preferably not greater than 400 mJ/cm² and most preferably not greater than 350 mJ/cm². If the energy density is too low, it becomes difficult to crystallize uniformly the metal oxide formed on the lateral faces of uneven sections or the like. In particular, crystallization of the metal oxide formed inside of a hole with a high aspect ratio (the minimum value of the bore/the depth) or a hole with a small average bore becomes considerably difficult. On the other hand, when the energy density is too high, the metal oxide formed in the plane region other than the uneven sections may agglomerate and, in some cases, bring about faults in the film growth in the subsequent manufacturing steps. A wavelength of the laser beam is, in general, selected appropriately; depending on the absorption wavelength of the metal oxide or the like, but a wavelength of 150-300 nm is preferably used. Irradiation of the laser beam with a wavelength of this sort, in practice, successfully achieves crystallization of the metal oxide formed inside of a hole. The metal oxide formed inside of a hole with a high aspect ratio is considered top be annealed by a laser light traveling into the inside of the hole, owing to the diffraction effect of the light, and thereby crystallized.

With respect to the irradiation method of the laser beam, there can be employed, for example, a method in which a laser beam having an irradiation region in the shape of a stripe or a rectangle is utilized, and successive irradiations of the laser beam are made while scanning. In this instance, successive irradiation regions are shifted in the direction of the minor axis in such a way that adjacent irradiation regions partially overlap and application of irradiations of the laser beam covers, in all, the whole prescribed region. Further, from the point of view of improving the productivity, the irradiation with a laser beam may be applied to the entire wafer at a time. Hereat, the laser irradiation can be made while heating the substrate. In this case, the heating temperature is preferably set at 200-400° C. or so. An excessively high temperature setting results in a drop of the element reliability.

As for the laser irradiation, while the present embodiment employs a method of irradiating the substrate from the direction normal thereto, it is possible to irradiate obliquely from a direction whose deviating angle from the direction normal to the substrate is within a range of 0.01-50°. This can provide an ample energy to the film inside of the sunken section and improve the quality of the crystallization.

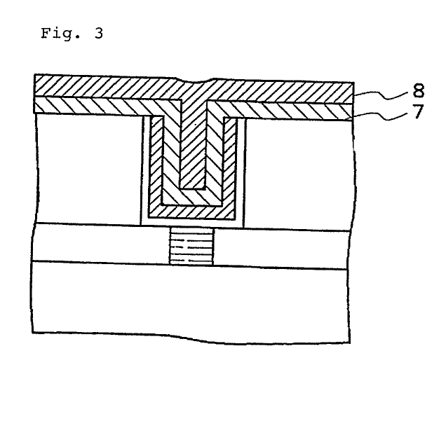

After the laser irradiation, an upper electrode film 8 is formed (FIG. 3). Dry etching is then performed to separate the capacitor insulating film 7 and the upper electrode film 8 into each chip. As described above, the formation of a capacitor comprising the adhesive film 5, the lower electrode film 6, the capacitor insulating film 7 and the upper electrode film 8 is, thereby, accomplished.

In the present embodiment, ruthenium films are utilized as electrode films, but, in addition to this, a ruthenium oxide film, a platinum film and a layered film of an iridium film and an iridium oxide film can be given as examples. Further, thickness of respective films constituting the capacitor are appropriately set, depending on the bore of the sunken section shown in the drawings or the like. Further, if a metal oxide such as ruthenium oxide is utilized for electrode films, the laser irradiation can be applied also to the crystallization of this metal oxide.

Further, although, in the present embodiment, a capacitor is formed in the sunken section set in the insulating film lying on the semiconductor substrate, a sunken section can be set directly in a semiconductor substrate and a capacitor, formed therein. Further, a raised section may be set on an insulating film lying on a semiconductor substrate, and a capacitor film may be formed thereon. In this case, the capacitor takes the shape of so-called cylinder type one, and the capacitor film is to be formed on the external wall of the raised section. Further, in addition to these, the present invention can be applied to the formation of a variety of stack type capacitors.

Second Embodiment

In First Embodiment described above, if the energy of the laser irradiation is too high, there are instances where agglomeration of the capacitor insulating film 7 occurs in the plane region other than the sunken section and creates the projecting sections. Therefore, in the present embodiment, the metal oxide formed in the region other than the sunken section is removed by means of CMP.

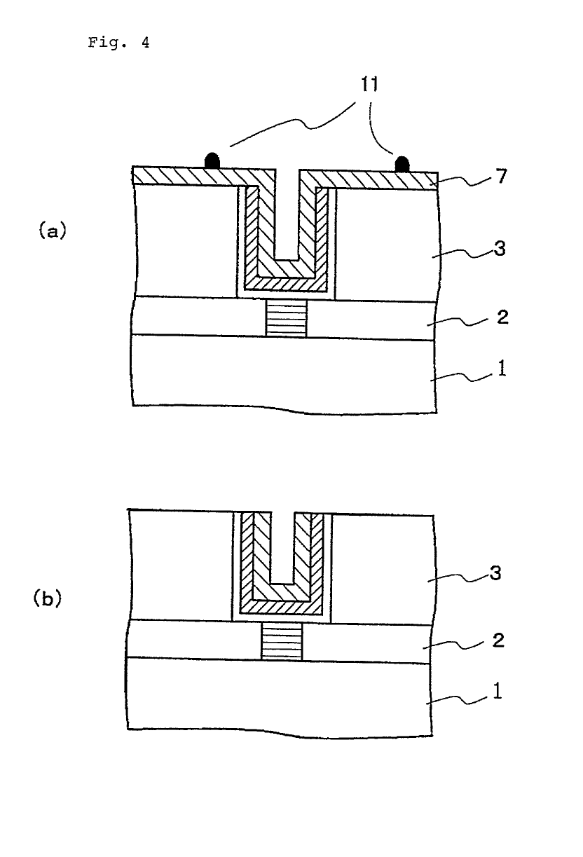

First, the steps up to FIG. 2(c) are carried out in the same way as First Embodiment, and then the laser irradiation is applied to the capacitor insulating film 7. At this, agglomeration of the capacitor insulating film may take place and, in some cases, create projecting sections 11, as shown in FIG. 4(a). Thus, the CMP is applied to the whole wafer until the interlayer insulating film 3 is exposed (FIG. 4(b)). After that, the inside of the sunken section may be cleaned, using a cleaning agent of APM (Ammonia-Hydrogen Peroxide) or such.

By carrying out the above steps, anomalous bodies created by the laser irradiation can be removed, which can enhance the reliability of the element.

Third Embodiment

In the present embodiment, after the inside of the sunken section is filled up with a prescribed material, the metal oxide formed in the region other than the sunken section is removed by means of CMP.

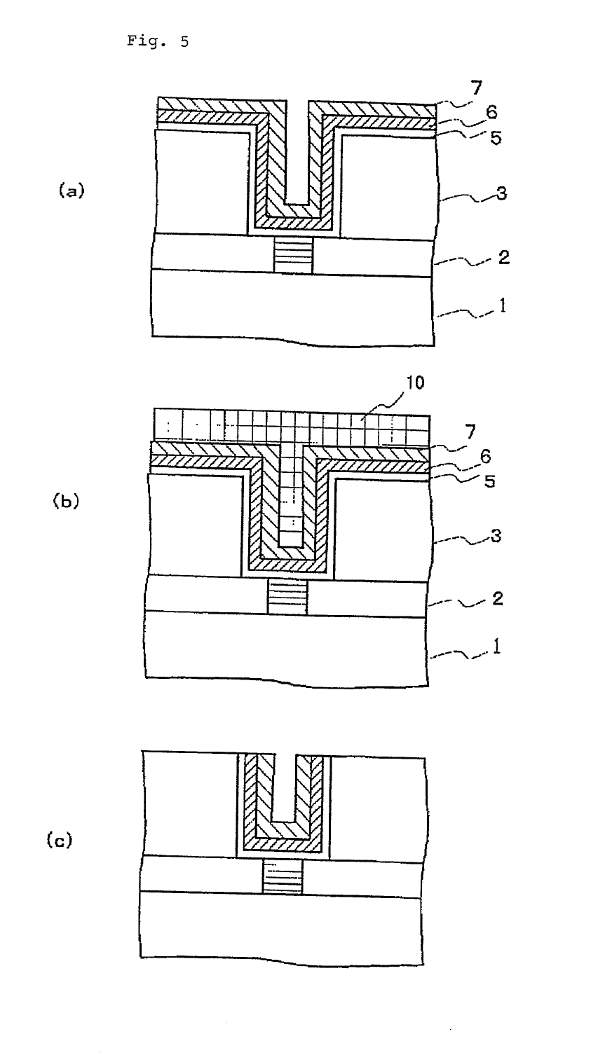

First, as shown in FIG. 5(c), after a contact hole is set in the interlayer insulating film 3, layers of an adhesive film 5, a lower electrode film 6 and a capacitor insulating film 7 are laid. Coating with a resist material 10 is then applied to the entire surface to fill up the inside of the hole (FIG. 5(b)). After that, the whole wafer is subjected to the CMP until the interlayer insulating film 3 becomes exposed. The resist material remaining inside of the hole is removed, using oxygen plasma ashing and a resist peeling-off agent (FIG. 5(c)). The resist peeling-off agent is chosen appropriately, depending on the material of the interlayer insulating film 3 and such, and, for example, a solution containing amines, a solution containing salt of ammonium fluoride or such can be employed.

By carrying out the above steps, the state in which the amorphous capacitor insulating film 7 is present only inside of the sunken section is brought about. Consequently, application of the laser irradiation in this state does not give rise to a problem of creating anomalous bodies in the region other than the sunken section so that the laser beam with a high energy density suitable to irradiate the inside of the sunken section can be selected. As a result, the capacitor insulating film 7 inside of the sunken section can be crystallized thoroughly and a capacitor element capable to provide the stable performance can be obtained.

Although the laser irradiation is made in the stage shown in FIG. 5(c) in the present embodiment, the laser irradiation can be conducted in the stage shown in FIG. 5(a). In this instance, irradiation with a laser beam having a high energy density may induce agglomeration of the capacitor insulating film 7 in the plane section and create projecting sections, as shown in FIG. 4(a). Yet, in the step after FIG. 5(b), the region other than the sunken section is subjected to polishing and removing so that the creation of the projecting sections does not cause a problem.

Herein, for the material to fill up the inside of the sunken section, in addition to the resist material, coating type materials such as SOG (Spin On Glass), HSQ (Hydrogen Silisesquioxane), MSQ (Methyl Silisesquioxane) or silica can be given as examples. In this case, buried HSQ or the like can be removed by a diluted hydrofluoric acid solution or such.

### EXAMPLES

Case for Reference

On a silicon wafer, a Ta₂O₅ film with a thickness of 15 nm was formed over the entire surface by the CVD method. Pulse irradiation with a XeCl excimer laser was then applied to this Ta₂O₅ film. The irradiation conditions were as follows.

Laser wavelength: 308 nm

Laser frequency: 290 Hz

Number of shots: 20 shots

Shape of the laser irradiation region: Stripe-shaped

Profile of the irradiation region in the direction of the laser progress: Mesa-shaped

Average energy density (Energy density in the top flat section): 300 mJ/cm²

During the irradiation, the laser irradiation regions moves in a given direction, in such a way that 95% of the irradiation regions overlap.

Analysis of the X-ray diffraction for the crystal structure of the Ta₂O₅ film after the laser irradiation showed a peak of the (0 0 1) plane of Ta₂O₅ as well as a peak of the (2 0 0) plane of Ta₂O₅ very distinctly.

Meanwhile, analysis of the X-ray diffraction for the crystal structure of the Ta₂O₅ film that is subjected to the RTA annealing instead of the laser irradiation showed a peak of the (0 0 1) plane of Ta₂O₅ as well as a peak of the (2 0 0) plane of Ta₂O₅.

The above results have confirmed that, like the RTA treatment, the irradiation with the XeCl laser can provide the excellent crystal structure.

### Example

An interlayer insulating film made of SiO₂ was formed on a silicon wafer. The interlayer insulating film was then dry etched so that a hole, 2 μm in depth, having a bottom face in the shape of an ellipse with a major axis of 0.35 μm and a minor axis of 0.3 μm may be formed therein.

Subsequently, after a Ta₂O₅ film with a thickness of 15 nm was formed over the entire surface by the CVD method, a portion of the Ta₂O₅ film lying outside of the hole was removed by means of CMP.

Pulse irradiation with a XeCl excimer laser was applied to the Ta₂O₅ film inside the hole that was obtained as described above. The irradiation conditions were as follows.

Laser wavelength: 308 nm

Laser frequency: 290 Hz

Number of shots: 20 shots

Shape of the laser irradiation region: Stripe-shaped

Profile of the irradiation region in the direction of the laser progress: Mesa-shaped

Average energy density (Energy density in the top flat section): 300 mJ/cm²

During the irradiation, the laser irradiation regions moves in a given direction, in such a way that 95% of the irradiation regions overlap.

Analysis of the X-ray diffraction for the crystal structure of the Ta₂O₅ film which was formed on the internal wall of the sunken section was made after the laser irradiation and showed a peak of the (0 0 1) plane of Ta₂O₅ as well as a peak of the (2 0 0) plane of Ta₂O₅ very distinctly, similar to the results of Case for Reference. This confirmed that crystallization of the Ta₂O₅ dielectric film formed in the sunken section by the laser was also successfully accomplished with effect.

What is claimed is:

1. A method of manufacturing a semiconductor device; which comprises the step of depositing an amorphous metal oxide on a surface of a semiconductor substrate where a sunken section or a raised section is set, and thereafter crystallizing said metal oxide by irradiation of a laser beam.

2. A method of manufacturing a semiconductor device according to claim 1; wherein an energy density of said laser beam is not less than 100 mJ/cm² but not greater than 450 mJ/cm².

3. A method of manufacturing a semiconductor device according to claim 1; wherein said metal oxide is Ta₂O₅, BST (BaₓSr₁₋ₓTiO₃), PZT (PbZrₓTi₁₋ₓO₃), PLZT (Pb_{1-y}La_{y}ZrₓTi₁₋ₓO₃) or SrBi₂Ta₂O₉ (0<x<1, 0<y<1).

4. A method of manufacturing a semiconductor device according to claim 1; wherein said sunken section is either a hole or a trench having a depth of 0.2 μm or greater.

5. A method of manufacturing a semiconductor device; which comprises the first step of forming an interlayer insulating film having a sunken section on a semiconductor substrate and thereafter forming a lower electrode layer i n a region including the internal wall of said sunken section and depositing an amorphous metal oxide thereon; the second step of crystallizing said metal oxide by irradiation of a laser beam; and the third step of forming an upper electrode layer on said metal oxide.

6. A method of manufacturing a semiconductor device according to claim 5; which, between the second step and the third step, further comprises the step of polishing the surface in the region other than the sunken section by means of chemical mechanical polishing.

7. A method of manufacturing a semiconductor device according to claim 5; wherein the lower electrode layer is composed of a metal material that contains one or more elements selected from the group consisting of Ru, Pt and Ir.

8. A method of manufacturing a semiconductor device according to claim 5; wherein the lower electrode layer is composed of a material that contains Ti, Ta or W.

9. A method of manufacturing a semiconductor device according to claim 5; wherein an energy density of said laser beam is not less than 100 mJ/cm² but not greater than 450 mJ/cm².

10. A method of manufacturing a semiconductor device according to claim 5; wherein said metal oxide is Ta₂O₅, BST (BaₓSr₁₋ₓTiO₃), PZT (PbZrₓTi₁₋ₓO₃), PLZT (Pb_{1-y}La_{y}ZrₓTi₁₋ₓO₃) or SrBi₂Ta₂O₉ (0<x<1, 0<y<1).

11. A method of manufacturing a semiconductor device according to claim 5; wherein said sunken section is either a hole or a trench having a depth of 0.2 μm or greater.

12. A method of manufacturing a semiconductor device according to claim 5; which, between the first step and the second step, further comprises the step of removing said metal oxide formed in the region other than the sunken section by means of chemical mechanical polishing.

13. A method of manufacturing a semiconductor device according to claim 12; which, between the second step and the third step, further comprises the step of polishing the surface in the region other than the sunken section by means of chemical mechanical polishing.

14. A method of manufacturing a semiconductor device according to claim 12; wherein the lower electrode layer is composed of a metal material that contains one or more elements selected from the group consisting of Ru, Pt and Ir.

15. A method of manufacturing a semiconductor device according to claim 12; wherein the lower electrode layer is composed of a material that contains Ti, Ta or W.

16. A method of manufacturing a semiconductor device according to claim 12; wherein an energy density of said laser beam is not less than 100 mJ/cm² but not greater than 450 mJ/cm².

17. A method of manufacturing a semiconductor device according to claim 12; wherein said metal oxide is Ta₂O₅, BST (BaₓSr₁₋ₓTiO₃), PZT (PbZrₓTi₁₋ₓO₃), PLZT (Pb_{1-y}La_{y}ZrₓTi₁₋ₓO₃) or SrBi₂Ta₂O₉ (0<x<1, 0<y<1).

18. A method of manufacturing a semiconductor device according to claims 12; wherein said sunken section is either a hole or a trench having a depth of 0.2 μm or greater.
